(19) United States
(12) Patent Application Publication
(10) Pub. No.: US 2014/0332258 A1
(43) Pub. Date: Nov. 13, 2014

(54) DOUBLE-SIDED PRINTED WIRING BOARD AND METHOD FOR PRODUCING THE SAME

(71) Applicants: SUMITOMO ELECTRIC PRINTED CIRCUITS, INC., Koka-shi, Shiga (JP); SUMITOMO ELECTRIC INDUSTRIES, LTD., Osaka-shi, Osaka (JP)

(72) Inventors: Yoshifumi Uchida, Koka-shi (JP); Yoshio Oka, Osaka-shi (JP); Takashi Kasuga, Osaka-shi (JP)

(21) Appl. No.: 14/368,869

(22) PCT Filed: Aug. 20, 2013
(86) PCT No.: PCT/JP2013/072150

§ 371 Date: Jun. 26, 2014

(30) Foreign Application Priority Data
Aug. 29, 2012 (JP) 2012-189195

(51) Int. Cl. H05K 1/11; H05K 3/40

(52) U.S. Cl. CPC H05K 1/116; H05K 3/4038; H05K 2201/0939; H05K 2201/09481; H05K 2203/1453
USPC 174/254; 174/262; 29/852

(57) ABSTRACT

An object of the present invention is to provide a double-sided printed wiring board in which a blind via hole can be easily and reliably formed, which can be accurately applied to lands of a surface-mounted component that are arranged at a narrow pitch, and in which an impedance mismatch can be effectively suppressed. The double-sided printed wiring board according to the present invention includes a substrate having an insulating property, a first conductive pattern stacked on a surface of the substrate and having a first land portion, a second conductive pattern stacked on another surface of the substrate and having a second land portion opposing the first land portion, and a blind via hole penetrating through the first land portion and the substrate, in which an average diameter of an outer shape of the first land portion is larger than an average diameter of an outer shape of the second land portion. The blind via hole, the first land portion, and the second land portion preferably have substantially circular outer shapes, and are preferably formed so as to be substantially concentric with each other.

### TECHNICAL FIELD

The present invention relates to a double-sided printed wiring board and a method for producing the same.

### BACKGROUND ART

Publicly known examples of double-sided printed wiring boards include a flexible printed wiring board in which a conductive pattern is provided on each of a top surface and a bottom surface of a flexible substrate, a rigid printed wiring board including a hard substrate, and a rigid-flexible printed wiring board including a hard substrate and a flexible substrate that are stacked one on top of the other. As shown in FIG. 3, the flexible printed wiring board 101 includes a substrate 102 and conductive patterns 103 and 104 that are stacked on a top surface and a bottom surface of the substrate 102. The conductive patterns 103 and 104 include circular land portions 105 having the same diameter at positions opposing each other. A hole 108 for a blind via hole is formed in the substrate 102 and one of the land portions 105 disposed on the top surface side. The hole 108 for a blind via hole is filled with a conductive paste by printing and this conductive paste is cured, thereby forming a blind via hole 107. Thus, the land portions 105 on the top surface and the bottom surface are electrically connected to each other (refer to Japanese Unexamined Patent Application Publication No. 62-120096).

### CITATION LIST

### Patent Literature

PTL 1: Japanese Unexamined Patent Application Publication No. 62-120096

### SUMMARY OF INVENTION

### Technical Problem

Regarding a double-sided printed wiring board such as the existing flexible printed wiring board 101, in the case where lands of a surface-mounted component are arranged at a narrow pitch, for example, in the case of a flip chip, it may be difficult to arrange the land portions 105. From this viewpoint, it is also conceivable that small land portions 105 of the flexible printed wiring board are provided so as to correspond to the lands of the surface-mounted component that are arranged at a narrow pitch. However, in the case where the size of the land portions 105 is decreased, in the formation of the blind via hole 107, it is difficult to accurately print a conductive paste to fill a hole for a blind via hole with the conductive paste, which may result in a decrease in the printing yield.

Furthermore, the land portions 105 usually have a larger width than other portions of a circuit pattern and the capacitance of the capacitor of the land portions 105 is large. Therefore, an impedance mismatch may be generated by the land portions 105.

The present invention has been made in view of the disadvantages described above. An object of the present invention is to provide a double-sided printed wiring board in which a blind via hole is easily and reliably formed, which can be accurately applied to lands of a surface-mounted component that are arranged at a narrow pitch, and in which an impedance mismatch can be effectively suppressed, and a method for producing the double-sided printed wiring board.

### Solution to Problem

A double-sided printed wiring board according to the present invention made in order to solve the above problems is a double-sided printed wiring board including:

a substrate having an insulating property;

a first conductive pattern stacked on a surface of the substrate and having a first land portion;

a second conductive pattern stacked on another surface of the substrate and having a second land portion opposing the first land portion; and

a blind via hole penetrating through the first land portion and the substrate,

in which an average diameter of an outer shape of the first land portion is larger than an average diameter of an outer shape of the second land portion.

According to the double-sided printed wiring board, since an average diameter of an outer shape of a first land portion is larger than an average diameter of an outer shape of a second land portion, a blind via hole can be easily and reliably formed. Specifically, for example, in the case where a blind via hole is formed by printing a conductive paste in a hole for the blind via hole, and curing the conductive paste, a deviation of the printing position of the conductive paste can be accurately absorbed by the relatively wide first land portion, and the hole for the blind via hole can be easily and reliably filled with the conductive paste. Therefore, an electrical conductor is easily and reliably formed.

In addition, since the average diameter of the outer shape of the second land portion is smaller than the average diameter of the outer shape of the first land portion, second land portions can be easily arranged at a narrow pitch. Therefore, this structure can also be applied to a case where lands are arranged at a narrow pitch, for example, a case of a flip chip. In addition, even in such a case, the decrease in the ease of the formation of a blind via hole can be effectively suppressed. Furthermore, since the second land portion has a small outer shape, the capacitance of the capacitor of this second land portion is smaller than that of an existing capacitor, and thus an impedance mismatch can be effectively suppressed.

In the double-sided printed wiring board, the outer shapes of the blind via hole, the first land portion, and the second land portion may be formed so as to be substantially circular shapes. With this structure, even a small blind via hole or the like is easily and reliably formed.

The first land portion is preferably arranged so as to be substantially concentric with the blind via hole. With this structure, a deviation in the plane direction in the formation of an electrical conductor can be reliably absorbed by the first land portion provided so as to be substantially concentric with the blind via hole, and the electrical conductor can be more accurately formed. The second land portion is preferably arranged so as to be substantially concentric with the blind via hole. With this structure, the second land portion is bonded to the substrate with a uniform strength in the circumferential direction.

The average diameter of the outer shape of the second land portion is preferably 5/6 times or less the average diameter of the outer shape of the first land portion. With this structure, second land portions can be easily arranged at a narrow pitch, and a deviation in the plane direction in the formation of a blind via hole can be reliably absorbed by the first land portion.

The average diameter of the outer shape of the first land portion is preferably 2 times or more an average diameter of an outer shape of the blind via hole. With this structure, a deviation in the plane direction in the formation of an electrical conductor can be reliably absorbed by the first land portion.

The average diameter of the outer shape of the second land portion is preferably 4 times or less an average diameter of an outer shape of the blind via hole. With this structure, second land portions can be easily arranged at a narrow pitch.

In the double-sided printed wiring board, the substrate preferably has flexibility. With this structure, the double-sided printed wiring board can be used as a flexible printed wiring board.

The blind via hole is preferably formed by curing a conductive paste containing a conductive particle. With this structure, an electrical conductor constituting the blind via hole can be easily and reliably formed by filling a hole for the blind via hole with a conductive paste by printing, and curing the conductive paste.

The blind via hole preferably includes a combined body of conductive particles each having a flattened spherical shape. With this structure, an electrically conducting state between the second land portion and the first land portion is reliably maintained by the combined body of conductive particles.

A method for producing a double-sided printed wiring board according to the present invention made in order to solve the above problems is a method for producing a double-sided printed wiring board, the method including the steps of:

forming, on a surface of a substrate having an insulating property, a first conductive pattern having a first land portion;

forming, on another surface of the substrate, a second conductive pattern having a second land portion opposing the first land portion;

forming a hole for a blind via hole, the hole penetrating through the first land portion and the substrate; and

printing, in the hole for the blind via hole, a conductive paste containing a conductive particle,

in which an average diameter of an outer shape of the first land portion is larger than an average diameter of an outer shape of the second land portion.

According to the method for producing a double-sided printed wiring board, the double-sided printed wiring board having the structure described above can be formed, and thus the advantages described above are achieved. Specifically, according to the method for producing a double-sided printed wiring board, since the average diameter of the outer shape of the first land portion is larger than the average diameter of the outer shape of the second land portion, a deviation of the printing position of the conductive paste can be accurately absorbed by the first land portion, and a blind via hole can be easily and reliably formed. In addition, according to the method for producing a double-sided printed wiring board, since the average diameter of the outer shape of the second land portion is smaller than the average diameter of the outer shape of the first land portion, second land portions can be easily arranged at a narrow pitch. Therefore, it is possible to produce a double-sided printed wiring board in which lands are arranged at a narrow pitch, for example, a double-sided printed wiring board for a flip chip. Furthermore, according to the method for producing a double-sided printed wiring board, since the second land portion can be formed so as to have a small shape, the capacitance of the capacitor of the second land portion is small, and thus an impedance mismatch can be effectively suppressed.

Herein, the term “outer shape” refers to the maximum outer shape in a plane projection shape parallel to a substrate. The term “average diameter” refers to an average of the maximum width of the outer shape and a width of the outer shape in a direction perpendicular the direction of the maximum width. The term “outer shape of a blind via hole” refers to an outer shape of an electrical conductor disposed in a hole for a blind via hole, the hole penetrating through a first land portion and a substrate, and does not include a shape of the electrical conductor that overflows from the blind via hole and is stacked on the surface of the first land portion. The term “substantially circular shape” means that 85% or more of an outer edge constitutes a circular arc, and a ratio of an average distance (average radius) of the circular arc from the center to a radius at each point constituting the circular arc is 85% or more and 115% or less. Furthermore, the term “substantially concentric” means that a distance between the centers of circles is 1/10 or less of the diameter of one of the circles having a larger diameter.

### Advantageous Effects of Invention

According the double-sided printed wiring board and the method for producing the double-sided printed wiring board, it is possible to obtain a double-sided printed wiring board in which a blind via hole can be easily and reliably formed, which can be accurately applied to lands arranged at a narrow pitch, and in which an impedance mismatch can be effectively suppressed.

### BRIEF DESCRIPTION OF DRAWINGS

FIG. 1 is an explanatory view of a double-sided printed wiring board according to an embodiment of the present invention, and is a schematic end view in a direction perpendicular to a substrate.

FIG. 2 includes schematic end views illustrating a method for producing the double-sided printed wiring board shown in FIG. 1. Part A shows a state before a first conductive pattern and a second conductive pattern are formed, part B shows a state after the first conductive pattern and the second conductive pattern are formed, part C shows a state where a hole for a blind via hole is formed in a substrate, and part D shows a state where a blind via hole is formed.

FIG. 3 is an explanatory view of an existing double-sided printed wiring board, and is a schematic end view in a direction perpendicular to a substrate.

### REFERENCE SIGNS LIST

1 flexible printed wiring board
2 substrate
3 first conductive pattern
4 second conductive pattern
5 first land portion
6 second land portion
7 blind via hole
8 hole for blind via hole

### DESCRIPTION OF EMBODIMENTS

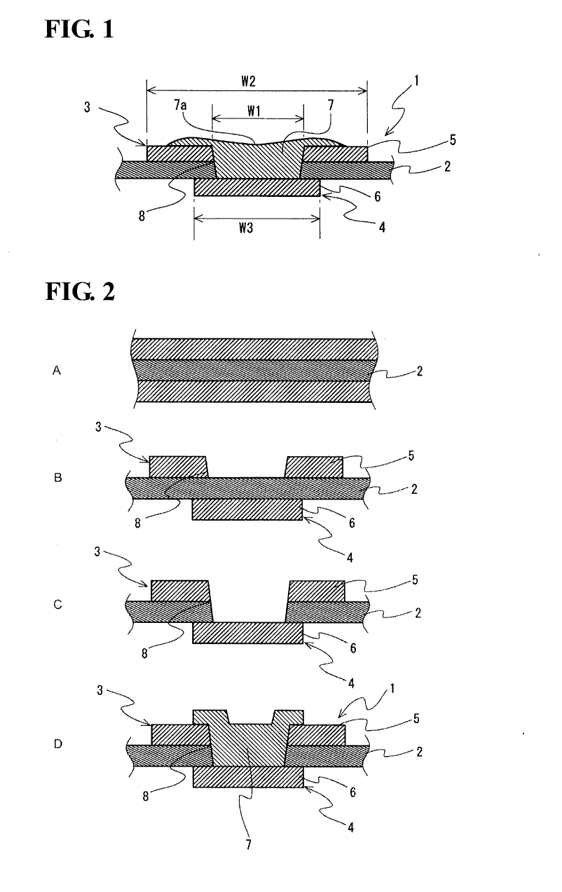

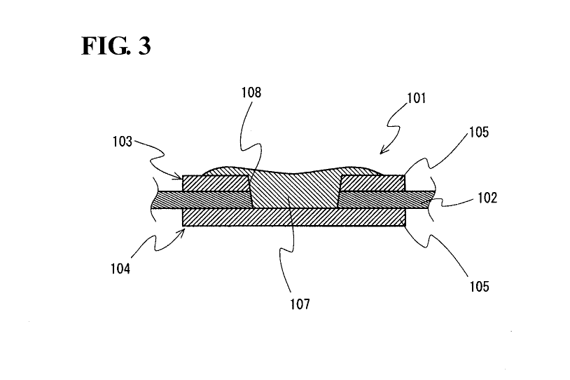

Embodiments of the present invention will now be described. First, a flexible printed wiring board will be described as an embodiment of a double-sided printed wiring board according to the present invention with reference to FIG. 1.

### [Flexible Printed Wiring Board]

A flexible printed wiring board 1 shown in FIG. 1 includes a substrate 2 having an insulating property, a first conductive pattern 3 stacked on one surface (hereinafter also referred to as “printing surface”) of the substrate 2, and a second conductive pattern 4 stacked on another surface (hereinafter also referred to as “mounting surface”) of the substrate 2. The first conductive pattern 3 includes a plurality of first land portions 5. The second conductive pattern 4 includes a plurality of second land portions 6 opposing the first land portions 5. The flexible printed wiring board 1 further includes a plurality of blind via holes 7 penetrating through the first land portions 5 and the substrate 2.

### (Substrate)

The substrate 2 is constituted by a sheet-like member having flexibility. Specifically, a resin film can be used as the substrate 2. For example, polyimide, polyethylene terephthalate, or the like can be suitably used as the material of the resin film.

An average thickness of the substrate 2 is not particularly limited, but is preferably 5 μm or more and 100 μm or less, and more preferably 10 μm or more and 50 μm or less. When the average thickness of the substrate 2 is less than the above lower limit, the strength of the substrate 2 may be insufficient. When the average thickness of the substrate 2 exceeds the above upper limit, such a thickness may be contrary to a requirement for a reduction of the thickness.

### (First Conductive Pattern)

The first conductive pattern 3 is formed so as to have a desired planar shape (pattern) by etching a metal layer stacked on the printing surface of the substrate 2. The first conductive pattern 3 can be formed by using a material having an electrical conductivity, and is generally formed by using, for example, copper. An average thickness of the first conductive pattern 3 is not particularly limited, but is preferably 2 μm or more and 30 μm or less, and more preferably 5 μm or more and 20 μm or less. When the average thickness of the first conductive pattern 3 is less than the lower limit, conductive properties may be insufficient. When the average thickness of the first conductive pattern 3 exceeds the upper limit, flexibility may be impaired.

Each of the first land portions 5 of the first conductive pattern 3 is provided so that an outer shape (outer peripheral edge) thereof is a substantially circular shape. The first land portion 5 has a hole 8 for a blind via hole at the center thereof, the hole 8 having a circular shape in plan view. The first land portion 5 is provided so as to have a ring shape in plan view as a whole. The outer peripheral edge and the inner peripheral edge of the first land portion 5 are formed in a concentric manner. The substrate 2 also has holes for blind via holes at positions corresponding to the holes 8 for blind via holes of the first land portions 5.

An outer diameter W2 (average diameter of the outer shape) of each of the first land portions 5 and an outer diameter W1 of each of the holes 8 for blind via holes (average diameter of an outer shape of a blind via hole 7) will be described later.

### (Second Conductive Pattern)

The second conductive pattern 4 is formed so as to have a desired planar shape (pattern) by etching a metal layer stacked on the back surface of the substrate 2 as in the first conductive pattern 3. Similarly to the first conductive pattern 3, the second conductive pattern 4 is formed by using, for example, copper. An average thickness of the second conductive pattern 4 is not particularly limited, but is preferably 2 μm or more and 30 μm or less, and more preferably 5 μm or more and 20 μm or less. When the average thickness of the second conductive pattern 4 is less than the lower limit, conductive properties may be insufficient. When the average thickness of the second conductive pattern 4 exceeds the upper limit, flexibility may be impaired.

Each of the second land portions 6 of the second conductive pattern 4 has an outer diameter larger than the hole 8 for a blind via hole, and is provided so as to close an opening of the hole 8 for a blind via hole, the opening being disposed on the mounting surface side. Each of the second land portions 6 is formed so that an outer shape thereof is a substantially circular shape. Specifically, the second land portion 6 is provided so as to be concentric with the corresponding first land portion 5 and the hole 8 for a blind via hole.

An outer diameter W3 (average diameter of the outer shape) of each of the second land portions 6 will be described later.

### (Blind via Hole)

Each of the blind via holes 7 electrically connects the corresponding first land portion 5 to the second land portion 6, and includes an electrical conductor that fills the hole 8 for a blind via hole. The blind via holes 7 are each formed by supplying a conductive paste containing conductive particles in the hole 8 for a blind via hole, and then curing the conductive paste. Specifically, the conductive paste is supplied by printing from the printing surface side into the hole 8 for a blind via hole. Accordingly, a bottom portion of the blind via hole 7 is in contact with the second land portion 6. The conductive paste overflows from the hole 8 for a blind via hole and covers a part of the first land portion 5.

The blind via hole 7 is formed by supplying the conductive paste and then curing the conductive paste after a certain period of time has passed. After the conductive paste is supplied, the conductive paste flows until it is cured. Consequently, a concave portion 7a is formed near the center of the blind via hole 7.

The conductive paste contains conductive particles and a binder resin. Metal particles are suitably used as the conductive particles. Silver, copper, nickel, or the like is suitably used as the material of the metal particles.

This conductive paste preferably contains conductive particles each having a flattened spherical shape (shape obtained by flattening a sphere). In this case, conductive particles, and a conductive particle and the second land portion 6 or the first land portion 5 easily contact each other, and a good electrical conductivity can be obtained. Regarding the shape of the flattened sphere, on a cross section including a minor axis and a major axis, the length of the minor axis is preferably 0.2 times or more and less than the length of the major axis, and more preferably 0.4 times or more and less than 0.8 times the length of the major axis. When the ratio of the minor axis to the major axis is within the above range, an electrical conductor having a good electrical conductivity can be obtained. The conductive particles each having a flattened spherical shape preferably have an average particle diameter (average of the length of the major axis) of 0.5 μm or more and 3 μm or less. When the average particle diameter is within the above range, an electrical conductor having a good electrical conductivity can be obtained. The conductive paste may contain a plurality of types of conductive particles having different average particle diameters.

In the formation of the blind via holes 7, the conductive paste is cured by heating. In this step, the conductive paste is heated at a temperature at which conductive particles are substantially combined with each other. Accordingly, the conductive particles are combined (combined by melting or combined by sintering) with each other in contact portions. That is, the electrical conductor includes a combined body of conductive particles. Note that the above-described conductive particles that are not combined with each other may be partly present.

Examples of the binder resin that can be used include epoxy resins, phenolic resins, polyester resins, acrylic resins, melamine resins, polyimide resins, polyamide-imide resins, and phenoxy resins. Thermosetting resins are suitably used as the binder resin.

The type of the epoxy resin is not particularly limited. For example, bisphenol-type epoxy resins obtained by using, as a raw material, bisphenol A, bisphenol S, bisphenol AD, or the like can be used. Naphthalene-type epoxy resins, novolak-type epoxy resins, biphenyl-type epoxy resins, dicyclopentadiene-type epoxy resins, and the like can also be used. Any of one-liquid epoxy resins and two-liquid epoxy resins can be used. One-liquid epoxy resins in which a microencapsulated curing agent is dispersed in an epoxy resin can also be used as the resin binder. In order to uniformly disperse a microencapsulated curing agent, butyl carbitol acetate or ethyl carbitol acetate can be used as a solvent of the conductive paste.

### (Regarding Diameters etc. of Respective Members)

The average diameter of the outer shape (outer diameter W1) of the blind via hole 7 is not particularly limited. However, the outer diameter W1 of the blind via hole 7 is preferably 20 μm or more and 150 μm or more less, more preferably 30 μm or more and 120 μm or more less, and still more preferably 40 μm or more and 100 μm or more less. When the outer diameter W1 of the blind via hole 7 is less than the lower limit, it may be difficult to fill the blind via hole 7 with an electrical conductor. On the other hand, when the outer diameter W1 of the blind via hole 7 exceeds the upper limit, the second land portion 6 described below may become excessively large as a result of the increase in the outer diameter W1 of the blind via hole 7. Note that the term “outer shape of a blind via hole 7” refers to an outer shape of a conductive paste cured in the hole 8 for a blind via hole, the outer shape not including the conductive paste that overflows from the hole 8 for a blind via hole and that covers the first land portion 5.

The plurality of blind via holes 7 are disposed in the form of a specific arrangement in plan view, for example, disposed in a grid pattern at a certain pitch in one direction and another direction in plan view. Here, the arrangement pitch of the blind via holes 7 is not particularly limited, but may be 100 μm or more and 500 μm or less.

The inner diameter of each of the first land portions 5 is substantially the same as the outer diameter of the hole 8 for a blind via hole. The outer diameter W2 (average diameter of the outer shape) of each of the first land portions 5 is larger than the outer diameter W3 of the corresponding second land portion 6. The outer diameter W2 of the first land portion 5 preferably has the following relationship with the outer diameter W1 of the blind via hole 7. That is, the outer diameter W2 of the first land portion 5 is preferably 2 times or more, more preferably 2.3 times or more, and still more preferably 2.5 times or more the outer diameter W1 of the blind via hole 7. With this structure, the printing yield of the conductive paste can be improved. On the other hand, the outer diameter W2 of the first land portion 5 is preferably 6 times or less, more preferably 5.5 times or less, and still more preferably 5 times or less the outer diameter W1 of the blind via hole 7. When the outer diameter W2 of the first land portion 5 exceeds the upper limit, the first land portion 5 becomes unnecessarily excessively large, and it may become difficult to design the first conductive pattern 3.

A width of the first land portion 5 in the radial direction (width between the inner peripheral edge and the outer peripheral edge ((W2−W1)/2)) is preferably 40 μm or more and 150 μm or less, and more preferably 45 μm or more and 125 μm or less. When the width of the first land portion 5 in the radial direction is less than the lower limit, the printing yield of the conductive paste may not be improved. When the width of the first land portion 5 in the radial direction exceeds the upper limit, it may become difficult to design the first conductive pattern 3.

Specifically, the outer diameter W2 of the first land portion 5 is preferably 100 μm or more and 400 μm or less, more preferably 130 μm or more and 380 μm or less, and still more preferably 150 μm or more and 350 μm or less. When the outer diameter W2 of the first land portion 5 is less than the lower limit, the printing yield of the conductive paste may be decreased. When the outer diameter W2 of the first land portion 5 exceeds the upper limit, it may become difficult to design the first conductive pattern 3.

The outer diameter W3 (average diameter of the outer shape) of the second land portion 6 is preferably 4 times or less, and more preferably 3 times or less the outer diameter W1 of the blind via hole 7. When the outer diameter W3 of the second land portion 6 exceeds the upper limit, it may become difficult to arrange the second land portions 6 at a narrow pitch, and an impedance mismatch may not be effectively suppressed. On the other hand, the outer diameter W3 of the second land portion 6 is preferably 1.2 times or more, and more preferably 1.5 times or more the outer diameter W1 of the blind via hole 7. When the outer diameter W3 of the second land portion 6 is less than the lower limit, an adhesive force between the second conductive pattern 4 and the substrate 2 in the second land portion 6, and a conductive property between the second land portion 6 and the blind via hole 7 may become insufficient.

The outer diameter W3 of the second land portion 6 is preferably 5/6 or less, and more preferably 5/7 or less the outer diameter W2 of the first land portion 5. On the other hand, the outer diameter W3 of the second land portion 6 is preferably 1/6 or more, and more preferably 1/3 or more the outer diameter W2 of the first land portion 5. When the ratio of the outer diameter W3 of the second land portion 6 to the outer diameter W2 of the first land portion 5 is within the above range, an improvement in the printing yield of the conductive paste and a narrow pitch of the second land portions 6 can be realized, and furthermore, an impedance mismatch can be effectively suppressed.

Specifically, the outer diameter W3 of the second land portion 6 is preferably 50 μm or more and 300 μm or less, more preferably 70 pm or more and 280 μm or less, and still more preferably 90 μm or more and 250 μm or less. When the outer diameter W3 of the second land portion 6 is less than the lower limit, an adhesive force between the second conductive pattern 4 and the substrate 2 in the second land portion 6 may become insufficient. When the outer diameter W3 of the second land portion 6 exceeds the upper limit, it may become difficult to arrange the second land portions 6 at a narrow pitch, and an impedance mismatch may not be effectively suppressed.

An area of the first land portion 5 (a ring-shaped area in plan view except for an opening area of the hole 8 for a blind via hole) is preferably 4 times or more and 50 times or less, and more preferably 5 times or more and 25 times or less an area of the blind via hole 7 (the opening area of the hole 8 for the blind via hole). With this structure, the printing yield of the conductive paste can be improved and the first conductive pattern 3 can be easily designed.

The area of the first land portion 5 (the ring-shaped area in plan view except for the opening area of the hole 8 for the blind via hole) is preferably 1.3 times or more and 5 times or less, and more preferably 1.8 times or more and 4 times or less an area of the second land portion 6. With this structure, both an improvement in the printing yield of the conductive paste and a narrow pitch of the second land portions 6 can be realized, and furthermore, an impedance mismatch can be effectively suppressed.

The area (the area in plan view) of the second land portion 6 is preferably 2.5 times or more and 20 times or less, and more preferably 2.7 times or more and 7 times or less the area of the blind via hole 7 (the opening area of the hole 8 for the blind via hole). When the area of the second land portion 6 is smaller than the lower limit, an adhesive force between the second conductive pattern 4 and the substrate 2 in the second land portion 6 may become insufficient. When the area of the second land portion 6 exceeds the upper limit, it may become difficult to arrange the second land portions 6 at a narrow pitch, and an impedance mismatch may not be effectively suppressed.

### [Method for Producing Flexible Printed Wiring Board]

Next, a method for producing the flexible printed wiring board 1 will be described with reference to FIG. 2. The method for producing the flexible printed wiring board 1 includes a first conductive pattern-forming step of forming, on a printing surface of a substrate 2, a first conductive pattern 3 having first land portions 5; a second conductive pattern-forming step of forming, on a mounting surface of the substrate 2, a second conductive pattern 4 having second land portions 6 opposing the first land portions 5; a hole for a blind via hole forming step of forming holes 8 for blind via holes, the holes 8 penetrating through the first land portions 5 and the substrate 2, as shown in part C of FIG. 2; and a blind via hole-forming step of forming blind via holes 7 in the holes 8 for blind via holes, as shown in part D of FIG. 2.

### (First Conductive Pattern-Forming Step and Second Conductive Pattern-Forming Step)

In the first conductive pattern-forming step and the second conductive pattern-forming step, a first conductive pattern 3 and a second conductive pattern 4 are formed on surfaces of a substrate 2 (refer to part B of FIG. 2). In these steps, second land portions 6 of the second conductive pattern 4 and first land portions 5 of the first conductive pattern 3 are formed at positions opposing each other. The shapes etc. of the second land portions 6 and the first land portions 5 are as described in the description of the flexible printed wiring board 1, and thus a description of the shapes etc. is omitted here. The second conductive pattern 4 and the first conductive pattern 3 can be formed by a publicly known method. For example, the second conductive pattern 4 and the first conductive pattern 3 can be formed as shown in part B of FIG. 2 by etching desired portions of metal layers stacked on surfaces of the substrate 2, as shown in part A of FIG. 2. The first conductive pattern-forming step and the second conductive pattern-forming step may be performed at the same time. Alternatively, these steps may be separately performed.

### (Hole for Blind via Hole Forming Step)

In the hole for a blind via hole forming step, holes 8 for blind via holes are perforated through the substrate 2 by irradiating the center of each of the ring-shaped first land portions 5 with a laser beam. Furthermore, after the irradiation with the laser beam, desmearing is performed to remove residues.

### (Blind via Hole-Forming Step)

The blind via hole-forming step includes a step of preparing a conductive paste containing conductive particles, a step of printing the conductive paste in the holes 8 for blind via holes, a step of allowing the conductive paste to stand for a certain period of time so that the printed conductive paste flows, and a step of curing, by heating, the conductive paste after the flow.

In the step of preparing a conductive paste, the conductive paste may be prepared such that a thixotropy index of the conductive paste is preferably 0.40 or less, and more preferably 0.25 or less. The thixotropy index is a value calculated by a formula (1) below.

Thixotropy index=log(η1/η2)/log(D2/D1) Formula (1)

D1 and D2 represent shear rates, and D1=2 s⁻¹, and D2=20 s⁻¹.
η1 represents a viscosity of a conductive paste at a shear rate of D1, and η2 represents a viscosity of the conductive paste at a shear rate of D2.

Furthermore, η1 is preferably 20 Pa·s or more and 300 Pa·s or less, and more preferably 40 Pa·s or more and 150 Pa·s or less. When the viscosity η1 is within the above range, the conductive paste can be easily and reliably printed in the holes 8 for blind via holes, and suitable blind via holes 7 can be formed.

A publicly known technique can be used as a specific printing method in the step of printing the conductive paste. For example, a screen printing method or an ink-jet printing method can be employed.

### Advantages

According to the flexible printed wiring board 1, the outer diameter of each of the first land portions 5 on the printing surface is larger than the outer diameter of the corresponding second land portion 6 on the mounting surface. With this structure, when the holes 8 for blind via holes are filled with a conductive paste, deviations of the printing positions of the conductive paste can be accurately absorbed by the relatively wide first land portions 5, and the holes 8 for blind via holes can be easily and reliably filled with the conductive paste. Therefore, the blind via holes 7 can be easily and reliably formed, and the printing yield can be improved.

In particular, since the outer shape of each of the blind via holes 7 and the outer shape of the corresponding first land portion 5 are substantially circular shapes that are concentric with each other in plan view, the first land portion 5 is uniformly provided on the outer circumference of the opening of the hole 8 for a blind via hole. Accordingly, even if a printing deviation occurs in any direction, a deviation of the printing position can be absorbed by the first land portion 5, and the printing yield can be further improved.

According to the flexible printed wiring board 1, since the outer diameter of each of the second land portions 6 is smaller than the outer diameter of the corresponding first land portion 5, the second land portions 6 can be arranged at a narrow pitch. Accordingly, the flexible printed wiring board 1 can be suitably applied to a component in which lands are arranged at a narrow pitch, for example, a flip chip.

Furthermore, since each of the second land portions 6 is small as described above, the capacitance of the capacitor of the second land portion 6 is smaller than that of an existing capacitor, and thus an impedance mismatch can be effectively suppressed.

Since the second land portions 6 are small as described above, flexibility near the first land portions 5 and the second land portions 6 of the flexible printed wiring board 1 is higher than that of an existing flexible printed wiring board in which land portions on respective surfaces have the same diameter.

### Other Embodiments

It is to be understood that the embodiments disclosed herein are only illustrative and not restrictive in all aspects. It is intended that the scope of the present invention is not limited to the configurations of the embodiments described above but is defined by the claims described below, and includes equivalents of the claims and all modifications within the scope of the claims.

Specifically, the above embodiments have been described by using a flexible printed wiring board as an example of a double-sided printed wiring board. However, the scope of the present invention is not limited thereto. A rigid printed wiring board may also be used as the double-sided printed wiring board. The double-sided printed wiring board may be applied to a rigid-flexible printed wiring board in which a flexible printed wiring board and a rigid printed wiring board are integrated with each other, a build-up substrate having a multilayer structure, or the like.

The relationship between the outer diameter of the first land portion 5 and the outer diameter of the second land portion 6 is not necessarily limited to the numerical ranges described in the above embodiments. Any structure in which the average diameter of the outer shape of the second land portion 6 is smaller than the average diameter of the outer shape of the first land portion 5 is within the scope of the present invention.

Furthermore, in the above embodiments, a description has been made of a case where the outer shapes of the blind via hole 7, the second land portion 6, and the first land portion 5 are each a substantially circular shape. However, the outer shapes of the blind via hole 7, the second land portion 6, and the first land portion 5 are not particularly limited. For example, the first land portions 5 may each have a quadrangular shape in plan view and may be arranged so as to be close to other adjacent first land portions 5 without contact each other. This arrangement is also matter of design variation. In this case, an insulating wall may be provided between the first land portions 5.

In the above embodiments, the outer shape of the blind via hole 7 and the outer shape of first land portion 5 are similar figures, but the present invention is not limited thereto. However, when the outer shape of the blind via hole 7 and the outer shape of first land portion 5 are similar figures as in the above embodiments, the width of the first land portion 5 (in the case where the first land portion 5 has a circular shape, the width of the first land portion 5 in the radial direction) becomes uniform. Therefore, this structure is advantageous in that the blind via hole 7 can be formed with a high accuracy.

### INDUSTRIAL APPLICABILITY

The present invention can be suitably used in, for example, a flexible printed wiring board or the like.

1. A double-sided printed wiring board comprising:
a substrate having an insulating property;
a first conductive pattern stacked on a surface of the substrate and having a first land portion;
a second conductive pattern stacked on another surface of the substrate and having a second land portion opposing the first land portion; and
a blind via hole penetrating through the first land portion and the substrate,
wherein an average diameter of an outer shape of the first land portion is larger than an average diameter of an outer shape of the second land portion.

2. The double-sided printed wiring board according to claim 1, wherein the outer shapes of the blind via hole, the first land portion, and the second land portion are formed so as to be substantially circular shapes.

3. The double-sided printed wiring board according to claim 2, wherein the first land portion is arranged so as to be substantially concentric with the blind via hole.

4. The double-sided printed wiring board according to claim 2, wherein the second land portion is arranged so as to be substantially concentric with the blind via hole.

5. The double-sided printed wiring board according to claim 1, wherein the average diameter of the outer shape of the second land portion is 5/6 times or less the average diameter of the outer shape of the first land portion.

6. The double-sided printed wiring board according to claim 1, wherein the average diameter of the outer shape of the first land portion is 2 times or more an average diameter of an outer shape of the blind via hole.

7. The double-sided printed wiring board according to claim 1, wherein the average diameter of the outer shape of the second land portion is 4 times or less an average diameter of an outer shape of the blind via hole.

8. The double-sided printed wiring board according to claim 1, wherein the substrate has flexibility.

9. The double-sided printed wiring board according to claim 1, wherein the blind via hole is formed by curing a conductive paste containing a conductive particle.

10. The double-sided printed wiring board according to claim 1, wherein the blind via hole includes a combined body of conductive particles each having a flattened spherical shape.

11. A method for producing a double-sided printed wiring board, the method comprising the steps of:
forming, on a surface of a substrate having an insulating property, a first conductive pattern having a first land portion;
forming, on another surface of the substrate, a second conductive pattern having a second land portion opposing the first land portion;
forming a hole for a blind via hole, the hole penetrating through the first land portion and the substrate; and
printing, in the hole for the blind via hole, a conductive paste containing a conductive particle,
wherein an average diameter of an outer shape of the first land portion is larger than an average diameter of an outer shape of the second land portion.
